(19) United States
(12) Patent Application Publication
(10) Pub. No.: US 2025/0155509 A1
(43) Pub. Date: May 15, 2025

(54) BATTERY STATE ESTIMATION APPARATUS, BATTERY STATE ESTIMATION METHOD, AND STORAGE MEDIUM

(71) Applicant: NEC Corporation, Minato-ku, Tokyo (JP)

(72) Inventors: Asako Fujii, Tokyo (JP); Takuroh Kashima, Tokyo (JP); Norihito Oi, Tokyo (JP); Yuki Chiba, Tokyo (JP)

(73) Assignee: NEC Corporation, Minato-ku, Tokyo (JP)

(21) Appl. No.: 18/838,274

(22) PCT Filed: Feb. 21, 2022
(86) PCT No.: PCT/JP2022/006867

§ 371 Date: Aug. 14, 2024

(51) Int. Cl. G01R 31/374; B60L 58/16; G01R 31/3835

(52) U.S. Cl. CPC G01R 31/374; B60L 58/16; G01R 31/3835; B60L 2240/662

(57) ABSTRACT

A battery state estimation apparatus (10) includes a vehicle data acquisition unit (110), a temperature data acquisition unit (120), and an estimation unit (140). The vehicle data acquisition unit (110) acquires vehicle stop location information and battery information. The vehicle stop location information indicates a vehicle stop location of a vehicle mounted with a battery. The battery information indicates a state of the battery at the location where the vehicle is stopped. The temperature data acquisition unit (120) acquires, by using the vehicle stop location information, temperature data being data relating to a temperature at the vehicle stop location. The estimation unit (140) estimates, by using the battery information and the temperature data, a state of the battery after the vehicle is stopped.

### TECHNICAL FIELD

The present invention relates to a battery state estimation apparatus, a battery state estimation system, a battery state estimation method, and a storage medium.

### BACKGROUND ART

A vehicle is frequently mounted with a battery. The battery is used, for example, as a power source when an engine is started. Further, in an electric vehicle, the battery is used as a power source of a motor. Therefore, when a remaining amount of the battery is decreased, sufficient output is not acquired from the battery, and as a result, the vehicle may not be operated.

In contrast, for example, Patent Document 1 descries the following battery monitoring apparatus. The battery monitoring apparatus computes, at a time of starting an engine, a voltage decrease amount from an output voltage of a battery detected by a voltage sensor, and also monitors, based on the computed voltage decrease amount, a state of a starter used for starting the engine. Then, the battery monitoring apparatus sets, based on the voltage decrease amount, in order to maintain the battery in a state where the engine can be started, an automatic start starting voltage V for starting the engine and starting charging. Further, Patent Document 1 describes that, when a voltage decrease amount is computed, accuracy can be improved when an influence of an environment such as temperature is considered.

### RELATED DOCUMENT

### Patent Document

Patent Document 1: Japanese Patent Application Publication No. 2006-327487

### DISCLOSURE OF THE INVENTION

### Technical Problem

In Patent Document 1 described above, an acquisition method for data relating to temperature is not described. Therefore, a work amount of a user required when data relating to temperature are acquired may be increased.

In view of the above-described problem, one example of an object of the present invention is to provide a battery state estimation apparatus, a battery state estimation system, a battery state estimation method, and a storage medium that are capable of estimating, by using data relating to temperature, a state of a battery and reducing an increase in a work amount of a user required when data relating to temperature are acquired.

### Solution to Problem

According to one aspect of the present invention, provided is a battery state estimation apparatus including:
a vehicle data acquisition unit that acquires vehicle stop location information indicating a vehicle stop location of a vehicle mounted with a battery, and also acquires battery information indicating a state of the battery at the location where the vehicle is stopped;
a temperature data acquisition unit that acquires, by using the vehicle stop location information, temperature data being data relating to a temperature at the vehicle stop location; and
an estimation unit that estimates, by using the battery information and the temperature data, a state of the battery after the vehicle is stopped.

According to one aspect of the present invention, provided is a battery state estimation system including:
a transmission apparatus mounted on a vehicle; and
a battery state estimation apparatus, wherein
the vehicle is mounted with a battery,
the transmission apparatus transmits, to the battery state estimation apparatus, vehicle stop location information indicating a vehicle stop location of the vehicle and battery information indicating a state of the battery at the location where the vehicle is stopped, and
the battery state estimation apparatus includes
   a vehicle data acquisition unit that acquires the vehicle stop location information and the battery information,
   a temperature data acquisition unit that acquires, by using the vehicle stop location information, temperature data being data relating to a temperature at the vehicle stop location, and
   an estimation unit that estimates, by using the battery information and the temperature data, a state of the battery after the vehicle is stopped.

According to one aspect of the present invention, provided is a battery state estimation method including,
by a computer:
   acquiring vehicle stop location information indicating a vehicle stop location of a vehicle mounted with a battery, and also acquiring battery information indicating a state of the battery at the location where the vehicle is stopped;
   acquiring, by using the vehicle stop location information, temperature data being data relating to a temperature at the vehicle stop location; and
   estimating, by using the battery information and the temperature data, a state of the battery after the vehicle is stopped.

According to one aspect of the present invention, provided is a computer-readable storage medium storing a program causing a computer to include:
a vehicle data acquisition function of acquiring vehicle stop location information indicating a vehicle stop location of a vehicle mounted with a battery, and also acquiring battery information indicating a state of the battery at the location where the vehicle is stopped;
a temperature data acquisition function of acquiring, by using the vehicle stop location information, temperature data being data relating to a temperature at the vehicle stop location; and
an estimation function of estimating, by using the battery information and the temperature data, a state of the battery after the vehicle is stopped.

### Advantageous Effects of Invention

According to one aspect of the present invention, a battery state estimation apparatus, a battery state estimation system, a battery state estimation method, and a storage medium that are capable of estimating, by using data relating to temperature, a state of a battery and reducing an increase in a work amount of a user required when data relating to temperature are acquired can be provided.

### BRIEF DESCRIPTION OF THE DRAWINGS

FIG. 1 is a diagram illustrating an outline of a battery state estimation apparatus according to a first example embodiment.

FIG. 2 is a diagram illustrating one example of a usage environment of the battery state estimation apparatus illustrated in FIG. 1.

FIG. 3 is a diagram illustrating one example of a usage environment of the battery state estimation apparatus.

FIG. 4 is a diagram illustrating one example of information stored in a history storage unit.

FIG. 5 is a diagram schematically illustrating one example of estimation information based on an estimation unit.

FIG. 6 is a diagram illustrating a hardware configuration example of the battery state estimation apparatus.

FIG. 7 is a flowchart illustrating a first example of processing executed by the battery state estimation apparatus.

FIG. 8 is a flowchart illustrating a detailed example of step S20 in FIG. 7.

FIG. 9 is a flowchart illustrating a second example of processing executed by the battery state estimation apparatus.

FIG. 10 is a diagram illustrating a modified example of the processing illustrated in FIG. 7.

FIG. 11 is a diagram illustrating a function configuration of a battery state estimation apparatus according to a second example embodiment.

FIG. 12 illustrates one example of information output by an output unit.

FIG. 13 is a diagram illustrating a function configuration of a battery state estimation apparatus according to a third example embodiment.

### EXAMPLE EMBODIMENT

Hereinafter, example embodiments according to the present invention are described by using the accompanying drawings. Note that, in all drawings, a similar component is assigned with a similar reference sign, and description thereof is omitted as appropriate.

### First Example Embodiment

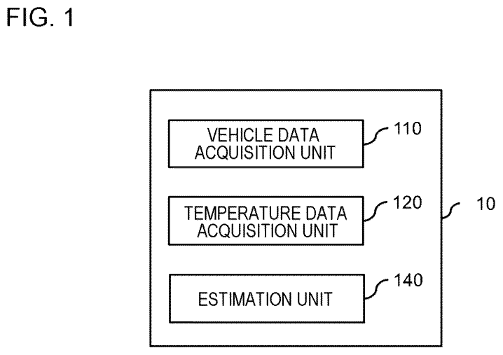

FIG. 1 is a diagram illustrating an outline of a battery state estimation apparatus 10 according to an example embodiment. The battery state estimation apparatus 10 includes a vehicle data acquisition unit 110, a temperature data acquisition unit 120, and an estimation unit 140. The vehicle data acquisition unit 110 acquires vehicle stop location information and battery information. The vehicle stop location information indicates a vehicle stop location of a vehicle mounted with a battery. One example of the vehicle stop location information is, but not limited to, latitude/longitude information. The battery information indicates a state of a battery at a location where the vehicle is stopped. The battery information includes, for example, but not limited to, at least one of an SOC and an output voltage. The temperature data acquisition unit 120 acquires, by using the vehicle stop location information, temperature data being data relating to a temperature at a vehicle stop location. The estimation unit 140 estimates, by using the battery information and the temperature data, a state of the battery after the vehicle is stopped. The state of the battery estimated herein includes, but not limited to, at least one of an SOC and an output voltage.

According to the battery state estimation apparatus 10, the estimation unit 140 estimates, by using battery information and temperature data, a state of a battery after a vehicle is stopped. Therefore, a user can recognize, during stop, whether a remaining amount of the battery may become insufficient. Further, the temperature data acquisition unit 120 acquires temperature data, by using vehicle stop location information. Therefore, a user does not need to work when acquiring data relating temperature.

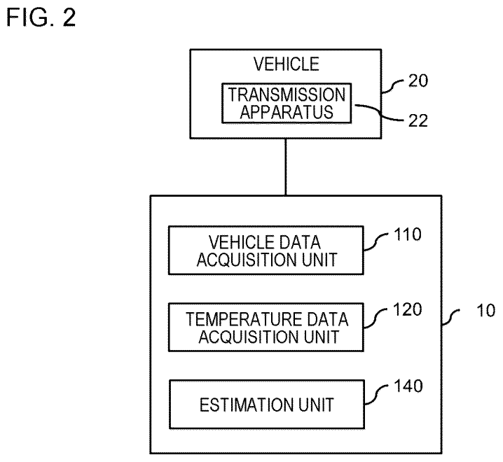

FIG. 2 is a diagram illustrating one example of a usage environment of the battery state estimation apparatus 10 illustrated in FIG. 1. In the example illustrated in the present figure, the battery state estimation apparatus 10 acquires, from a transmission apparatus 22 mounted on a vehicle 20, vehicle stop location information and battery information. Then, the battery state estimation apparatus 10 and the transmission apparatus 22 are at least a part of a battery state estimation system.

Hereinafter, a detailed example of the battery state estimation apparatus 10 is described.

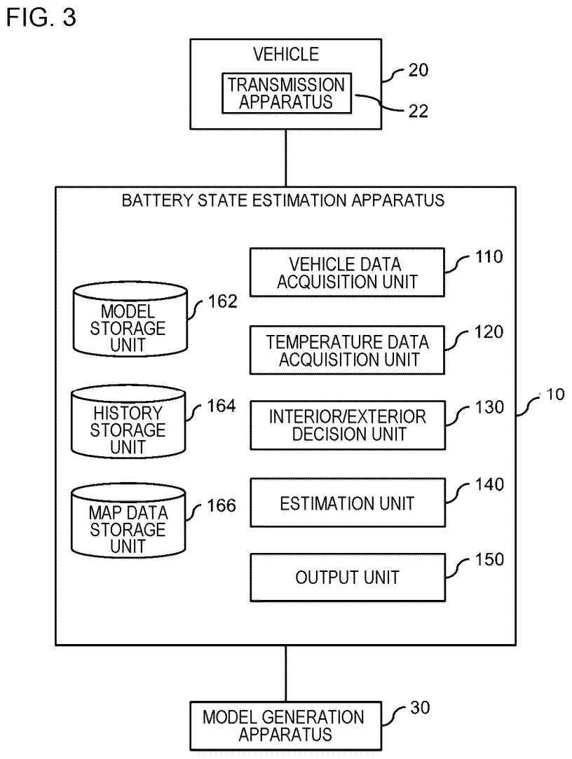

FIG. 3 is a diagram illustrating a detailed example of a usage environment of the battery state estimation apparatus 10. The battery state estimation apparatus 10 is carried, for example, by at least one of a user, an owner, or an administrator of the vehicle 20. The battery state estimation apparatus 10 may be a portable communication terminal, for example, such as a smartphone and a tablet terminal, or may be a fixed apparatus.

The transmission apparatus 22 transmits, when the vehicle 20 is stopped, vehicle stop location information and battery information to the battery state estimation apparatus 10. Further, the transmission apparatus 22 transmits, when the vehicle 20 being stopped is started, start information indicating the fact to the battery state estimation apparatus 10.

Note that, a matter that the “vehicle 20 is being stopped” denotes that, when the vehicle 20 includes an engine, the engine is being stopped, and denotes that, when the vehicle 20 is an electric vehicle, power is not being supplied to a motor or a control unit that controls the power supply is being turned off.

Further, the battery state estimation apparatus 10 is used together with a model generation apparatus 30, in addition to the transmission apparatus 22. The estimation unit 140 of the battery state estimation apparatus 10 uses, when estimating a state of a battery, a model generated based on machine learning. The model generation apparatus 30 generates the model, and causes the battery state estimation apparatus 20 to store the generated model.

Then, the battery state estimation apparatus 10 includes, as described above, the vehicle data acquisition unit 110, the temperature data acquisition unit 120, and the estimation unit 140. Further, the battery state estimation apparatus 10 further includes an interior/exterior decision unit 130, an output unit 150, a model storage unit 162, a history storage unit 164, and a map data storage unit 166.

The model storage unit 162 stores a model generated by the model generation apparatus 30.

The history storage unit 164 stores a history of various types of data for each vehicle. The data stored in the history storage unit 164 include vehicle stop location information, battery information, and an estimation result based on the estimation unit 140.

The map data storage unit 166 stores map data. The map data also include location information, for example, information indicating presence/absence of a building in the location for each of pieces of latitude/longitude information. Further, the map data include, when a building is present, information indicating whether a temperature sensor is present inside the building, for example, in a parking space, and also a method of acquiring a detection result from the temperature sensor.

Note that, at least one of the model storage unit 162, the history storage unit 164, and the map data storage unit 166 may be located outside the battery state estimation apparatus 10.

The vehicle data acquisition unit 110, as described by using FIGS. 1 and 2, acquires vehicle stop location information and battery information from the transmission apparatus 22 mounted on the vehicle 20, and causes the history storage unit 164 to store the acquired data.

The vehicle stop location information indicates a location where the vehicle 20 is stopped. One example of the vehicle stop location information is latitude/longitude information indicating a vehicle stop location. In this case, the vehicle 20 generates latitude/longitude information, for example, by using a GPS.

The battery information includes, as described by using FIG. 1, a parameter indicating a state of a battery included in the vehicle 20. The parameter includes, as described above, but not limited to, at least one of an SOC and an output voltage.

The temperature data acquisition unit 120, as described by using FIG. 1, acquires temperature data being data relating to a temperature at a vehicle stop location by using vehicle stop location information, and causes the history storage unit 164 to store the acquired data. At that time, the temperature data acquisition unit 120 uses a decision result based on the interior/exterior decision unit 130. One example of the temperature data is an actual measurement value of temperature. However, the temperature data may include, in addition to the actual measurement value, an estimation value and a prediction value of temperature.

The interior/exterior decision unit 130 decides, by using vehicle stop location information, whether a vehicle stop location is indoor or outdoor. At that time, the interior/exterior decision unit 130 uses map data stored in the map data storage unit 166.

Then, the temperature data acquisition unit 120 acquires, when the vehicle stop location is outdoor, temperature data measured at a measurement spot nearest to the vehicle stop location information, from an external data server, for example, a server of the Japan Meteorological Agency.

On the other hand, the temperature data acquisition unit 120 executes, when the vehicle stop location is indoor, any of the following pieces of processing.
1) The temperature data acquisition unit 120 acquires, from an external data server, for example, a server of the Japan Meteorological Agency, temperature data measured at a measurement spot nearest to vehicle stop location information.
2) The temperature data acquisition unit 120 acquires, when map data indicate that a temperature sensor is present in a building relevant to a vehicle stop location, a detection result of the temperature sensor as temperature data.

The estimation unit 140 estimates, as described by using FIG. 1, by using battery information and temperature data, a state of a battery after a vehicle is stopped. Hereinafter, the estimation result based on the estimation unit 140 is described as estimation information. The estimation information includes, for example, an estimation value of a parameter of a battery, for example, an estimation value of at least one of an SOC and an output voltage.

For more details, the estimation information includes, for example, at least one of the following pieces of information.
A) An estimation value of a parameter of a battery after elapse of a predetermined time. A predetermined period is, but not limited to, after one week or after two weeks.
B) An estimation result of a temporal change in a parameter of a battery. An estimation value of a parameter of a battery, for example, in each of a plurality of elapsed times (e.g., after one day, after seven days, and after fourteen days).

The estimation unit 140 uses, when generating estimation information, a model stored in the model storage unit 162. The model is generated by the model generation apparatus 30. An explanatory variable of the model includes at least battery information at a time of being stopped and temperature data of a vehicle stop location. Further, an objective variable of the model is the above-described estimation information.

Herein, temperature data included in the explanatory variable may indicate transition of a temperature at a vehicle stop location after the vehicle 20 is stopped. The transition may be an actual measurement value, or may be a prediction value. In the case of the latter, a prediction value of temperature is acquired, for example, from an external data server.

Note that, the temperature data acquisition unit 120 and the estimation unit 140 may execute the above-described processing repeatedly, for example, every 24 hours. In this case, when temperature data acquired by the temperature data acquisition unit 120 include an actual measurement value of temperature, an actual measurement value repeatedly acquired by the temperature data acquisition unit 120 indicates transition of a temperature after a stop at a vehicle stop location. Then, these actual measurement values are stored in the history storage unit 164. The estimation unit 140 determines transition of temperature by using data stored in the history storage unit 164, and thereby, may generate estimation information by using the transition. In this case, the explanatory variable of a model stored in the model storage unit 162 includes the transition.

Further, the vehicle data acquisition unit 110 may also repeatedly acquire battery information from the transmission apparatus 22. In this case, the estimation unit 140 may generate estimation information every time the vehicle data acquisition unit 110 acquires battery information. In the estimation, the temperature data acquisition unit 120 preferably acquires latest temperature data and causes the estimation unit 140 to use the acquired data.

Further, in this case, the battery information repeatedly acquired by the vehicle data acquisition unit 110 indicates transition of a performance value of a parameter of a battery. Then, these performance values are stored in the history storage unit 164. The estimation unit 140 determines, by using data stored in the history storage unit 164, transition of a parameter of the battery, and thereby, may generate estimation information by using the transition. In this case, the explanatory variable of a model stored in the model storage unit 162 includes the transition.

Further, the estimation unit 140 corrects, when a vehicle stop location of the vehicle 20 is indoor, temperature data acquired from an external data server by the temperature data acquisition unit 120, and thereby, may generate estimation information, by using the corrected temperature data. Generally, temperature data stored in an external data server indicate an outdoor temperature. Therefore, the estimation unit 140 corrects temperature data acquired by the temperature data acquisition unit 120 to a higher temperature side, and thereby causes the data to be close to an indoor temperature. Thereby, the estimation unit 140 can accurately estimate a state of a battery.

Note that, the estimation unit 140 may correct, even when a vehicle stop location of the vehicle 20 is outdoor, temperature data acquired by the temperature data acquisition unit 120. One example in which the correction is required is a case where an altitude difference between a vehicle stop location of the vehicle 20 and a measurement spot of temperature data is equal to or more than a reference value.

Further, the estimation unit 140 associates estimation information with information indicating estimation timing, and thereby, may cause the history storage unit 164 to store the associated information. In this case, the estimation unit 140 may generate estimation information, by further using at least one of estimation information in a past, i.e., past information, and temperature data used when the past information is generated. In this case, the explanatory variable of a model stored in the model storage unit 162 further includes information to be used herein.

The output unit 150 outputs estimation information. The output unit 150 outputs estimation information, for example, to a display included in the battery state estimation apparatus 10 or an external printing apparatus.

Further, the output unit 150 performs a predetermined output when estimation information satisfies a reference, i.e., when an output condition is satisfied. The reference used herein is that, for example, at least one of an SOC and a voltage included in the estimation information falls below a reference value. In this case, the predetermined output performed by the output unit 150 indicates that a remaining amount of a battery is insufficient and due to the fact, the vehicle 20 may not be started.

Note that, a detailed example of an output condition for predetermined information is, for example, at least any one of the following conditions.
a) A case where, among pieces of estimation information of the estimation unit 140, an estimation value relevant to a current date and time falls below a reference value. In this case, the predetermined output indicates, according to a set content of a reference value, that a remaining amount of a battery may be already insufficient.
b) In addition to the condition of a), a case where a vehicle is not started until a current time, i.e., timing at which a remaining amount of a battery falls below a reference value.
c) A case where, among pieces of estimation information of the estimation unit 140, an estimation value relevant to “after a predetermined time from a current date and time” falls below a reference value. This is a case where while a remaining amount of a battery is currently sufficient, after a predetermined time, for example, after 24 hours, the remaining amount of the battery is highly likely to be insufficient. In this case, the predetermined output indicates that, when a predetermined time elapses without starting the vehicle 20 as is, a remaining amount of a battery may become insufficient.

Further, in addition to the above-described condition, the output unit 150 may perform the predetermined output when it is estimated, from estimation information, that the vehicle 20 is being stopped for a predetermined time or more in an environment having a temperature equal to or more than a first temperature or equal to or less than a second temperature. Herein, the first temperature is selected, for example, from a temperature equal to or more than 30° C. Further, the second temperature is selected, for example, from a temperature equal to or less than 0° C.

Then, the output unit 150 may output, after performing the predetermined output, predetermined information repeatedly, for example, every 24 hours until acquiring, from the transmission apparatus 22, start information, i.e., information indicating that the vehicle 20 is started.

Note that, the battery state estimation apparatus 10 may be a cloud server. In this case, the output unit 150 outputs estimation information and also performs the above-described predetermined output to a terminal carried by at least one of a user, an owner, or an administrator of the vehicle 20. Then, the terminal displays the estimation information, and also displays the predetermined output.

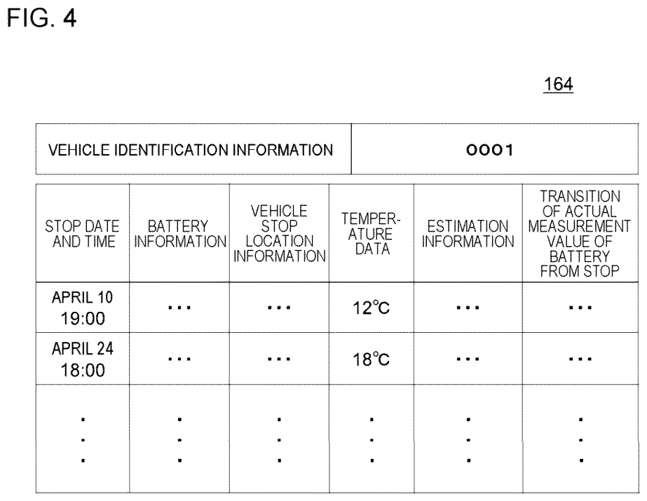

FIG. 4 is a diagram illustrating one example of information stored in the history storage unit 164. The history storage unit 164 stores vehicle identification information for each vehicle, and also stores a stop date and time of the vehicle, in association with each of battery information at stop timing, vehicle stop location information, temperature data, estimation information, and battery information from the stop, i.e., transition of an actual measurement value of a parameter of the battery. Note that, the temperature data may indicate an actual measurement value or a prediction value of transition of a temperature at a vehicle stop location after the vehicle 20 is stopped.

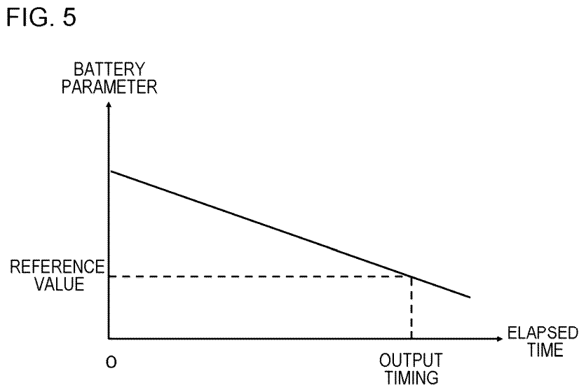

FIG. 5 is a diagram schematically illustrating one example of estimation information based on the estimation unit 140. In an example illustrated in the present figure, the estimation information indicates an estimation result of transition of a parameter of a battery since the vehicle 20 is stopped, for example, an estimation result of transition of an SOC and an output voltage. Then, the output unit 150 performs the predetermined output when, for the parameter, timing of falling below a reference value comes.

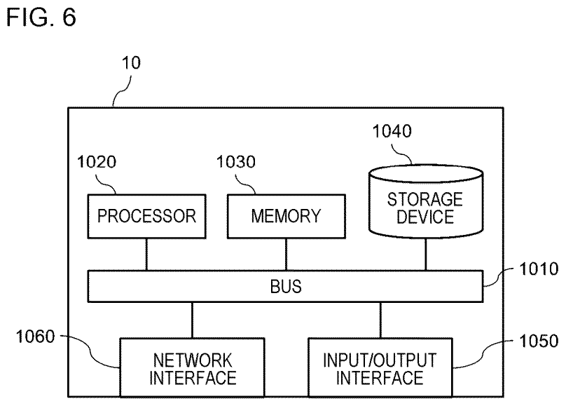

FIG. 6 is a diagram illustrating a hardware configuration example of the battery state estimation apparatus 10. The battery state estimation apparatus 10 includes a bus 1010, a processor 1020, a memory 1030, a storage device 1040, an input/output interface 1050, and a network interface 1060.

The bus 1010 is a data transmission path through which the processor 1020, the memory 1030, the storage device 1040, the input/output interface 1050, and the network interface 1060 transmit/receive data to/from one another. However, a method of mutually connecting the processor 1020 and the like is not limited to bus connection.

The processor 1020 is a processor achieved by a central processing unit (CPU), a graphics processing unit (GPU), or the like.

The memory 1030 is a main storage apparatus achieved by a random access memory (RAM) or the like.

The storage device 1040 is an auxiliary storage apparatus achieved by a hard disk drive (HDD), a solid state drive (SSD), a removable medium such as a memory card, a read only memory (ROM), or the like. The storage device 1040 stores a program module achieving each function (e.g., the vehicle data acquisition unit 110, the temperature data acquisition unit 120, the interior/exterior decision unit 130, the estimation unit 140, and the output unit 150) of the battery state estimation apparatus 10. The processor 1020 reads each of the program modules onto the memory 1030 and executes the read program module, and thereby achieves each function relevant to the program module. Further, the storage device 1040 functions as at least a part of the model storage unit 162, the history storage unit 164, and the map data storage unit 166.

The input/output interface 1050 is an interface for connecting the battery state estimation apparatus 10 and various types of input/output devices.

The network interface 1060 is an interface for connecting the battery state estimation apparatus 10 to a network. The network is, for example, a local area network (LAN) or a wide area network (WAN). A method of connecting to a network based on the network interface 1060 may be wireless connection or may be wired connection. The battery state estimation apparatus 10 communicates with the transmission apparatus 22 and the model generation apparatus 30 via the network interface 1060.

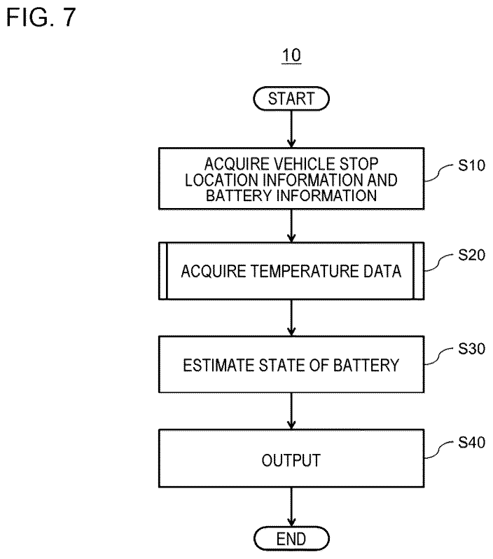

FIG. 7 is a flowchart illustrating a first example of processing executed by the battery state estimation apparatus 10. The transmission apparatus 22 generates, when the vehicle 20 is stopped, vehicle stop location information and battery information, and transmits the generated vehicle stop location information and battery information to the battery state estimation apparatus 10. The vehicle data acquisition unit 110 of the battery state estimation apparatus 10 acquires these pieces of vehicle stop location information and battery information (step S10).

Next, the temperature data acquisition unit 120 of the battery state estimation apparatus 10 acquires, by using the vehicle stop location information acquired in step S10, temperature data (step S20). At that time, the interior/exterior decision unit 130 of the battery state estimation apparatus 10 decides whether a vehicle stop location is indoor. Details of step S20 are described later by using another figure,

Next, the estimation unit 140 of the battery state estimation apparatus 10 generates estimation information. The estimation information indicates, as described above, a result of estimating a state of a battery after the vehicle is stopped (step S30). Details of processing executed by the estimation unit 140 are as described by using FIG. 3.

Next, the output unit 150 of the battery state estimation apparatus 10 outputs the estimation information (step S40).

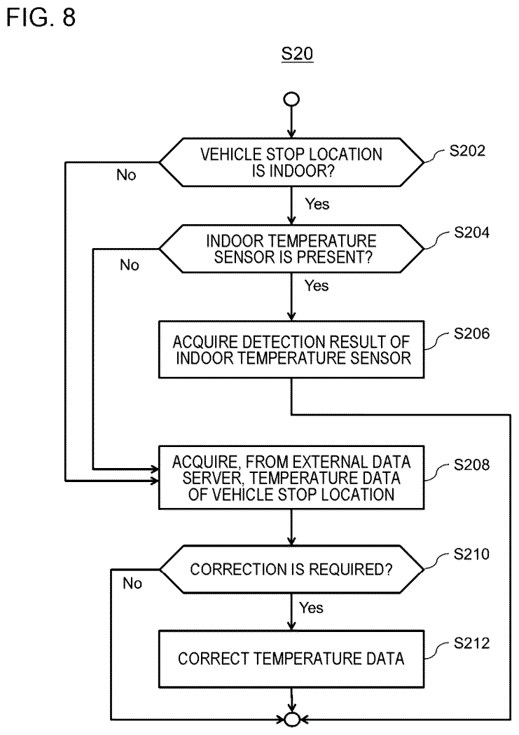

FIG. 8 is a flowchart illustrating a detailed example of step S20 in FIG. 7. First, the interior/exterior decision unit 130 decides, by using the vehicle stop location information and the map data storage unit 166, whether a vehicle stop location of the vehicle 20 is indoor (step S202).

The interior/exterior decision unit 130 decides, when the vehicle stop location is indoor (step S202: Yes), whether a temperature sensor is installed in a building relevant to the vehicle stop location of the vehicle 20, by using the map data storage unit 166. The temperature data acquisition unit 120 acquires, when a temperature sensor is present (step S204: Yes), a detection result of the temperature sensor. The temperature data acquisition unit 120 communicates, for example, with the temperature sensor, and acquires the detection result (step S206).

On the other hand, when the vehicle stop location is outdoor (step S202: No), or when a temperature sensor is not installed in the building relevant to the vehicle stop location of the vehicle 20 (step S204: No), the temperature data acquisition unit 120 acquires, from an external server, temperature data at a measurement spot nearest to a location indicated by the vehicle stop location information (step S208). Then, the estimation unit 140 corrects the temperature data as necessary (steps S210 and S212). An example in which the correction is required is a case where the vehicle stop location of the vehicle 20 is indoor, and a case where an altitude difference between the vehicle stop location of the vehicle 20 and a measurement spot of the temperature data is equal to or more than a reference value.

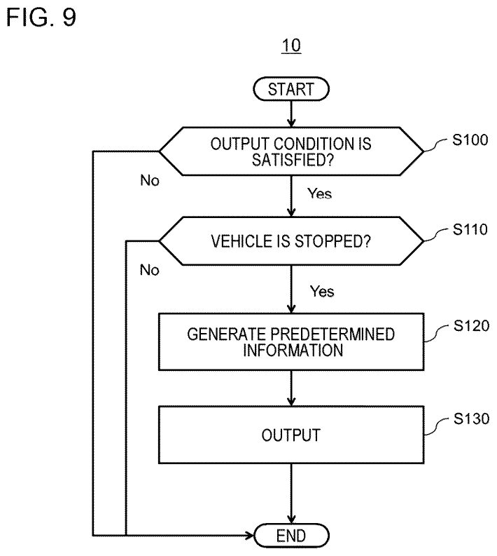

FIG. 9 is a flowchart illustrating a second example of processing executed by the battery state estimation apparatus 10. The present figure indicates processing for outputting, after the estimation unit 140 generates the estimation information, predetermined information by the output unit 150 as necessary. The output unit 15 repeatedly executes the processing, for example, every 24 hours.

First, the output unit 150 decides, at a current date and time, whether an output condition for predetermined information is satisfied (step S100). The predetermined information indicates, as described by using FIG. 3, that a remaining amount of a battery is insufficient and due to the fact, the vehicle 20 may not be started. Further, an example of the output condition is any of a) and c) described by using FIG. 3.

When the output condition is satisfied (step S100: Yes) and the vehicle 20 is not started yet (step S100: Yes), the output unit 150 generates predetermined information (step S120), and outputs the generated predetermined information (step S130). Note that, a specific example of an output destination is as described by using FIG. 3.

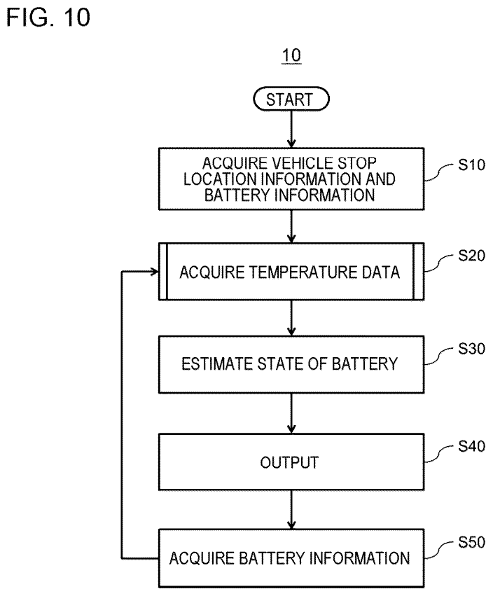

FIG. 10 is a diagram illustrating a modified example of the processing illustrated in FIG. 7. The example illustrated in the present figure is similar to the example illustrated in FIG. 7 except that acquisition of battery information, acquisition of temperature data, generation of estimation information, and output are repeatedly performed.

For details, after step S40, the vehicle data acquisition unit 110 acquires, after a predetermined time elapses, battery information (step S50). Thereafter, processing illustrated in step S20 to step S40 is executed.

As described above, according to the present example embodiment, the temperature data acquisition unit 120 acquires temperature data, by using vehicle stop location information of the vehicle 20. Then, the estimation unit 140 estimates, by using the temperature data, a state of a battery. Therefore, when the battery state estimation apparatus 10 is used, a state of a battery can be estimated by using data relating to temperature, and an increase in a work amount of a user required when data relating to temperature are acquired can be reduced.

Further, the interior/exterior decision unit 130 decides whether a vehicle stop location of the vehicle 20 is indoor. Then, when the vehicle stop location is indoor and a temperature sensor is provided in a building relevant to the interior, the temperature data acquisition unit 120 acquires temperature data from the temperature sensor. Therefore, accuracy of an estimation result of a state of a battery based on the estimation unit 140 is improved.

Further, when the vehicle stop location is indoor and a temperature sensor is not provided in a building relevant to the interior, the estimation unit 140 corrects temperature data acquired from an external data server, and estimates a state of a battery by using the corrected temperature data. Therefore, accuracy of an estimation result of the state of the battery based on the estimation unit 140 is improved.

### Second Example Embodiment

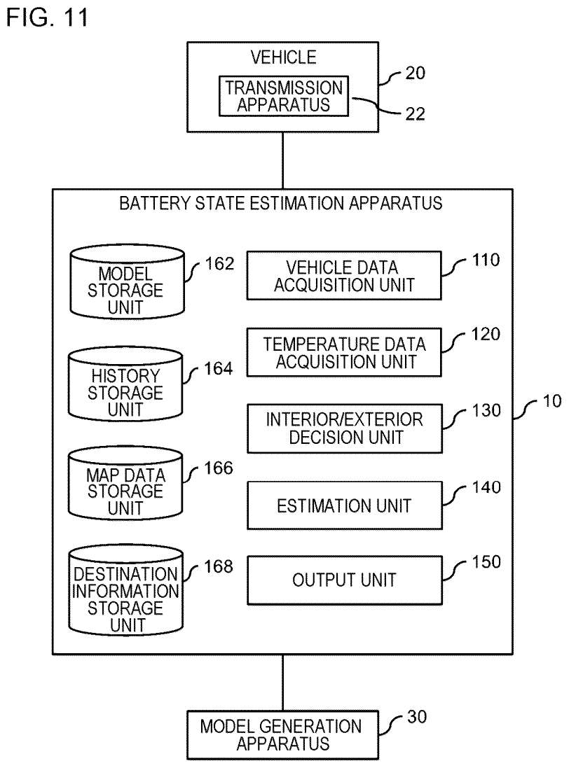

FIG. 11 is a diagram illustrating a function configuration of a battery state estimation apparatus 10 according to the present example embodiment, and is equivalent to FIG. 3 according to the first example embodiment. The battery state estimation apparatus 10 illustrated in the present figure is similar to the battery state estimation apparatus 10 according to the first example embodiment except the following point.

First, the battery state estimation apparatus 10 includes a destination information storage unit 168. The destination information storage unit 168 stores information relating to a location and a facility to be a candidate of a destination of a vehicle 20 being stopped. Hereinafter, the information is described as destination information. Then, an output unit 150 includes the destination information in a predetermined output.

As one example, the destination information storage unit 168 stores, as destination information, location information of the location or the facility and detailed information of the location or the facility in association with each other. The detailed information stored in the destination information storage unit 168 indicates, for example, an experienceable content and a purchasable product or service in the location or the facility. The detailed information may include advertisement information. Then, the output unit 150 selects, from the destination information storage unit 168, a location or a facility close to a location indicated by vehicle stop location information, and includes, in the predetermined output, location information and detailed information of the selected location or facility.

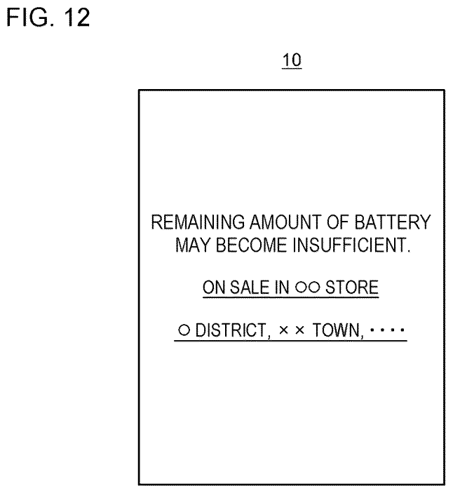

FIG. 12 illustrates one example of information output by the output unit 150 according to the present example embodiment. In the example illustrated in the present figure, the output unit 150 causes a display of the battery state estimation apparatus 10 to display information indicating that a remaining amount of a battery may become insufficient, and also location information and detailed information of a location to which the vehicle 20 should move.

Also, according to the present example embodiment, similarly to the first example embodiment, a state of a battery can be estimated by using data relating to temperature, and an increase in a work amount of a user required when data relating to temperature are acquired can be reduced. Further, the output unit 150 outputs location information and detailed information of a location to which the vehicle 20 should move. Therefore, the battery state estimation apparatus 10 can provide, for a user or an administrator of the vehicle 20, a cue for starting the vehicle 20.

### Third Example Embodiment

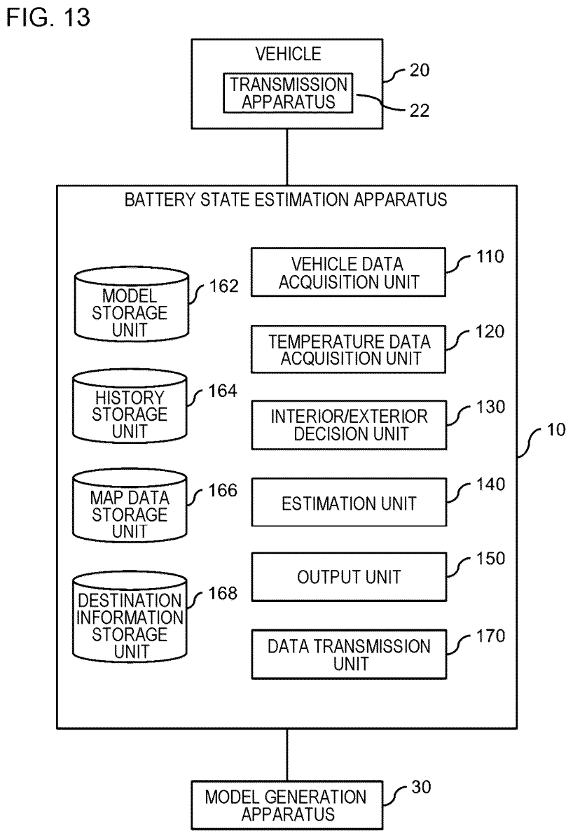

FIG. 13 is a diagram illustrating a function configuration of a battery state estimation apparatus 10 according to the present example embodiment, and is equivalent to FIG. 11 according to the second example embodiment. The battery state estimation apparatus 10 illustrated in the present figure is similar to the battery state estimation apparatus 10 according to the first or second example embodiment, except that a data transmission unit 170 is included.

The data transmission unit 170 determines, when a predetermined time elapses from a stop, a difference between an estimation result of a battery and an actual measurement value of a state of the battery, by using data stored in a history storage unit 164. Then, the data transmission unit 170 transmits, when the difference is equal to or more than a reference value, i.e., when an estimation result based on a model is separated, to a large extent, from the actual measurement value, at least the actual measurement value of the state of the battery and temperature data to an outside of the battery state estimation apparatus 10, for example, a model generation apparatus 30. The data transmitted by the data transmission unit 170 are used as at least a part of training data of machine learning.

Then, the model generation apparatus 30 updates the training data by using the data acquired from the data transmission unit 170. Then, the model generation apparatus 30 modifies a model by using the updated training data, and causes a model storage unit 162 of the battery state estimation apparatus 10 to store the modified model.

Note that, a reference value for transmitting data by the data transmission unit 170 is defined, for example, based on a reference that a sufficient output for starting an engine cannot be acquired from a battery.

Also, according to the present example embodiment, similarly to the first example embodiment, a state of a battery can be estimated by using data relating to temperature, and an increase in a work amount of a user required when data relating to temperature are acquired can be reduced. Further, the data transmission unit 170 transmits, when a difference between an estimation result of a battery and an actual measurement value of a state of the battery is equal to or more than a reference value, at least the actual measurement value of the state of the battery and temperature data to an outside for a purpose of re-learning of a model. Therefore, accuracy of a model used by the battery state estimation apparatus 10 is improved.

While with reference to the accompanying drawings, the example embodiments according to the present invention have been described, the example embodiments are exemplification of the present invention, and various configurations other than the above-described configurations are employable.

Further, in a plurality of flowcharts used in the above-described description, a plurality of steps (pieces of processing) are described in order, but an execution order of steps to be executed according to each example embodiment is not limited to the described order. According to each example embodiment, an order of illustrated steps can be modified within an extent that there is no harm in context. Further, each of the above-described example embodiments can be combined within an extent that there is no conflict in content.

The whole or part of the example embodiments described above can be described as, but not limited to, the following supplementary notes.

1. A battery state estimation apparatus including:
a vehicle data acquisition unit that acquires vehicle stop location information indicating a vehicle stop location of a vehicle mounted with a battery, and acquires battery information indicating a state of the battery at the location where the vehicle is stopped;
a temperature data acquisition unit that acquires, by using the vehicle stop location information, temperature data being data relating to a temperature at the vehicle stop location; and
an estimation unit that estimates, by using the battery information and the temperature data, a state of the battery after the vehicle is stopped.

2. The battery state estimation apparatus according to supplementary note 1, wherein
the temperature data acquisition unit acquires, from a weather information storage unit that stores temperature data for each of a plurality of spots, temperature data relevant to the vehicle stop location information,
the battery state estimation apparatus further including
an interior/exterior decision unit that decides, by using the vehicle stop location information, whether the vehicle stop location is indoor or outdoor, wherein
the estimation unit
   corrects, when the vehicle stop location is indoor, the temperature data and then estimates a state of the battery.

3. The battery state estimation apparatus according to supplementary note 1 or 2, further including
an interior/exterior decision unit that decides, by using the vehicle stop location information, whether the vehicle stop location is indoor or outdoor, wherein
the temperature data acquisition unit acquires, when the vehicle stop location is indoor, the temperature data from a temperature sensor installed in the vehicle stop location.

4. The battery state estimation apparatus according to any one of supplementary notes 1 to 3, wherein
the estimation unit estimates a state of the battery, by further using at least one of past information indicating a past estimation result based on the estimation unit, and the temperature data used when the past information is generated.

5. The battery state estimation apparatus according to any one of supplementary notes 1 to 4, wherein
the estimation unit
   determines, by using the temperature data, transition of a temperature at the vehicle stop location since the vehicle is stopped, and
   estimates, by using the transition of the temperature, a state of the battery.

6. The battery state estimation apparatus according to any one of supplementary notes 1 to 5, wherein,
until the vehicle is started after the vehicle is stopped,
the vehicle data acquisition unit repeatedly acquires the battery information, and
the estimation unit repeatedly estimates a state of the battery.

7. The battery state estimation apparatus according to any one of supplementary notes 1 to 6, further including
an output unit that performs a predetermined output when an estimation result based on the estimation unit satisfies a reference.

8. The battery state estimation apparatus according to supplementary note 7, wherein
the estimation result includes transition of a value indicating a battery remaining amount since the vehicle is stopped, and
the output unit performs the predetermined output when the vehicle is not started until timing at which, in the transition, the battery remaining amount becomes equal to or less than a reference value.

9. The battery state estimation apparatus according to supplementary note 7 or 8, wherein
the output unit repeatedly performs the predetermined output until the vehicle is started.

10. The battery state estimation apparatus according to any one of supplementary notes 7 to 9, wherein
the predetermined output includes destination information indicating a candidate of a destination of the vehicle.

11. The battery state estimation apparatus according to any one of supplementary notes 1 to 10, wherein
the estimation unit estimates a state of the battery, by using a model generated based on machine learning using, as an explanatory variable, the battery information and the temperature data, and, as an objective variable, a state of the battery,
the battery state estimation apparatus further including
a data transmission unit that transmits, to an outside, when a difference between an estimation result of the battery and an actual measurement value of a state of the battery is equal to or more than a reference in a case where a predetermined time elapses from the stop, at least an actual measurement value of a state of the battery and the temperature data in order to be used as at least a part of training data of the machine learning.

12. A battery state estimation system including:
a transmission apparatus mounted on a vehicle; and
a battery state estimation apparatus, wherein
the vehicle is mounted with a battery,
the transmission apparatus transmits, to the battery state estimation apparatus, vehicle stop location information indicating a vehicle stop location of the vehicle and battery information indicating a state of the battery at the location where the vehicle is stopped, and
the battery state estimation apparatus includes
   a vehicle data acquisition unit that acquires the vehicle stop location information and the battery information,
   a temperature data acquisition unit that acquires, by using the vehicle stop location information, temperature data being data relating to a temperature at the vehicle stop location, and
   an estimation unit that estimates, by using the battery information and the temperature data, a state of the battery after the vehicle is stopped.

13. The battery state estimation system according to supplementary note 12, wherein
the temperature data acquisition unit acquires, from a weather information storage unit that stores temperature data for each of a plurality of spots, temperature data relevant to the vehicle stop location information,
the battery state estimation apparatus further includes an interior/exterior decision unit that decides, by using the vehicle stop location information, whether the vehicle stop location is indoor or outdoor, and
the estimation unit
   corrects, when the vehicle stop location is indoor, the temperature data and then estimates a state of the battery.

14. The battery state estimation system according to supplementary note 12 or 13, wherein
the battery state estimation apparatus further includes an interior/exterior decision unit that decides, by using the vehicle stop location information, whether the vehicle stop location is indoor or outdoor, and
the temperature data acquisition unit acquires, when the vehicle stop location is indoor, the temperature data from a temperature sensor installed in the vehicle stop location.

15. The battery state estimation system according to any one of supplementary notes 12 to 14, wherein
the estimation unit estimates a state of the battery, by further using at least one of past information indicating a past estimation result based on the estimation unit, and the temperature data used when the past information is generated.

16. The battery state estimation system according to any one of supplementary notes 12 to 15, wherein
the estimation unit
   determines, by using the temperature data, transition of a temperature at the vehicle stop location since the vehicle is stopped, and
   estimates, by using the transition of the temperature, a state of the battery.

17. The battery state estimation system according to any one of supplementary notes 12 to 16, wherein,
until the vehicle is started after the vehicle is stopped,
the vehicle data acquisition unit repeatedly acquires the battery information, and
the estimation unit repeatedly estimates a state of the battery.

18. The battery state estimation system according to any one of supplementary notes 12 to 17, wherein
the battery state estimation apparatus includes an output unit that performs a predetermined output when an estimation result based on the estimation unit satisfies a reference.

19. The battery state estimation system according to supplementary note 18, wherein
the estimation result includes transition of a value indicating a battery remaining amount since the vehicle is stopped, and
the output unit performs the predetermined output when the vehicle is not started until timing at which, in the transition, the battery remaining amount becomes equal to or less than a reference value.

20. The battery state estimation system according to supplementary notes 18 or 19, wherein
the output unit repeatedly performs the predetermined output until the vehicle is started.

21. The battery state estimation system according to any one of supplementary notes 18 to 20, wherein
the predetermined output includes destination information indicating a candidate of a destination of the vehicle.

22. The battery state estimation system according to any one of supplementary notes 12 to 21, wherein
the estimation unit estimates a state of the battery, by using a model generated based on machine learning using, as an explanatory variable, the battery information and the temperature data, and, as an objective variable, a state of the battery, and
the battery state estimation apparatus further includes a data transmission unit that transmits, to an outside, when a difference between an estimation result of the battery and an actual measurement value of a state of the battery is equal to or more than a reference in a case where a predetermined time elapses from the stop, at least an actual measurement value of a state of the battery and the temperature data in order to be used as at least a part of training data of the machine learning.

23. A battery state estimation method including,
by a computer:
   acquiring vehicle stop location information indicating a vehicle stop location of a vehicle mounted with a battery, and also acquiring battery information indicating a state of the battery at the location where the vehicle is stopped;
   acquiring, by using the vehicle stop location information, temperature data being data relating to a temperature at the vehicle stop location; and
   estimating, by using the battery information and the temperature data, a state of the battery after the vehicle is stopped.

24. The battery state estimation method according to supplementary note 23. further including, by the computer:
acquires, from a weather information storage unit that stores temperature data for each of a plurality of spots, temperature data relevant to the vehicle stop location information;
deciding, by using the vehicle stop location information, whether the vehicle stop location is indoor or outdoor; and
correcting, when the vehicle stop location is indoor, the temperature data and then estimates a state of the battery.

25. The battery state estimation method according to supplementary note 23 or 24, further including,
by the computer:
   deciding, by using the vehicle stop location information, whether the vehicle stop location is indoor or outdoor; and
   acquiring, when the vehicle stop location is indoor, the temperature data from a temperature sensor installed in the vehicle stop location.

26. The battery state estimation method according to any one of supplementary notes 23 to 25, further including,
by the computer,
   estimating a state of the battery, by further using at least one of past information indicating the estimation result in past, the and temperature data used when the past information is generated.

27. The battery state estimation method according to any one of supplementary notes 23 to 26, further including,
by the computer:
   determining, by using the temperature data, transition of a temperature at the vehicle stop location since the vehicle is stopped; and
   estimating, by using the transition of the temperature, a state of the battery.

28. The battery state estimation method according to any one of supplementary notes 23 to 27, further including,
until the vehicle is started after the vehicle is stopped, by the computer:
   repeatedly acquiring the battery information; and
   repeatedly estimating a state of the battery.

29. The battery state estimation method according to any one of supplementary notes 23 to 28, further including,
by the computer,
   performing a predetermined output when an estimation result satisfies a reference.

30. The battery state estimation method according to supplementary note 29, wherein
the estimation result includes transition of a value indicating a battery remaining amount since the vehicle is stopped,
the battery state estimation method further including,
by the computer,
performing the predetermined output when the vehicle is not started until timing at which, in the transition, the battery remaining amount becomes equal to or less than a reference value.

31. The battery state estimation method according to supplementary note 29 or 30, further including,
by the computer,
   repeatedly performing the predetermined output until the vehicle is started.

32. The battery state estimation method according to any of supplementary notes 29 to 31, wherein
the predetermined output includes destination information indicating a candidate of a destination of the vehicle.

33. The battery state estimation method according to any of supplementary notes 29 to 32, further including,
by the computer:
   estimating a state of the battery, by using a model generated based on machine learning using, as an explanatory variable, the battery information and the temperature data, and, as an objective variable, a state of the battery; and
   transmitting, to an outside, when a difference between an estimation result of the battery and an actual measurement value of a state of the battery is equal to or more than a reference in a case where a predetermined time elapses from the stop, at least an actual measurement value of a state of the battery and the temperature data in order to be used as at least a part of training data of the machine learning.

34. A computer-readable storage medium storing a program for causing a computer to include:
a vehicle data acquisition function of acquiring vehicle stop location information indicating a vehicle stop location of a vehicle mounted with a battery, and also acquiring battery information indicating a state of the battery at the location where the vehicle is stopped;
a temperature data acquisition function of acquiring, by using the vehicle stop location information, temperature data being data relating to a temperature at the vehicle stop location; and
an estimation function of estimating, by using the battery information and the temperature data, a state of the battery after the vehicle is stopped.

35. The storage medium according to supplementary note 34, wherein the temperature data acquisition function acquires, from a weather information storage unit that stores temperature data for each of a plurality of spots, temperature data relevant to the vehicle stop location information,
the program further causes the computer to include an interior/exterior decision function of deciding, by using the vehicle stop location information, whether the vehicle stop location is indoor or outdoor, and
the estimation function
   corrects, when the vehicle stop location is indoor, the temperature data and then estimates a state of the battery.

36. The storage medium according to supplementary note 34 or 35, wherein
the program further causes the computer to include an interior/exterior decision function of deciding, by using the vehicle stop location information, whether the vehicle stop location is indoor or outdoor, and
the temperature data acquisition function acquires, when the vehicle stop location is indoor, the temperature data from a temperature sensor installed in the vehicle stop location.

37. The storage medium according to any one of supplementary notes 34 to 36, wherein
the estimation function estimates a state of the battery, by further using at least one of past information indicating the estimation result in past, and the temperature data used when the past information is generated.

38. The storage medium according to any one of supplementary notes 34 to 37, wherein
the estimation function
   determines, by using the temperature data, transition of a temperature at the vehicle stop location since the vehicle is stopped, and
   estimates, by using the transition of the temperature, a state of the battery.

39. The storage medium according to any one of supplementary notes 34 to 38, wherein,
until the vehicle is started after the vehicle is stopped,
the vehicle data acquisition function repeatedly acquires the battery information, and
the estimation function repeatedly estimates a state of the battery.

40. The storage medium according to any one of supplementary notes 34 to 39, wherein
the program causes the computer to include an output function of performing a predetermined output when an estimation result based on the estimation function satisfies a reference.

41. The storage medium according to supplementary note 40, wherein
the estimation result includes transition of a value indicating a battery remaining amount since the vehicle is stopped, and
the output function performs the predetermined output when the vehicle is not started until timing at which, in the transition, the battery remaining amount becomes equal to or less than a reference value.

42. The storage medium according to supplementary note 40 or 41, wherein
the output function repeatedly performs the predetermined output until the vehicle is started.

43. The storage medium according to any one of supplementary notes 40 to 42, wherein
the predetermined output includes destination information indicating a candidate of a destination of the vehicle.

44. The storage medium according to any one of supplementary notes 34 to 43, wherein
the estimation function estimates a state of the battery, by using a model generated based on machine learning using, as an explanatory variable, the battery information and the temperature data, and, as an objective variable, a state of the battery, and
the program causes the computer to include a data transmission function of transmitting, to an outside, when a difference between an estimation result of the battery and an actual measurement value of a state of the battery is equal to or more than a reference in a case where a predetermined time elapses from the stop, at least an actual measurement value of a state of the battery and the temperature data in order to be used as at least a part of training data of the machine learning.

45. The program according to any one of supplementary notes 34 to 44.

### REFERENCE SIGNS LIST

10 Battery state estimation apparatus
20 Vehicle
22 Transmission apparatus
30 Model generation apparatus
110 Vehicle data acquisition unit
120 Temperature data acquisition unit
130 Interior/exterior decision unit
140 Estimation unit
150 Output unit
162 Model storage unit
164 History storage unit
166 Map data storage unit
168 Destination information storage unit
170 Data transmission unit

What is claimed is:

1. A battery state estimation apparatus comprising:
at least one memory configured to store instructions; and
at least one processor configured to execute the instructions to preform operations comprising:
acquiring vehicle stop location information indicating a vehicle stop location of a vehicle mounted with a battery, and also acquiring battery information indicating a state of the battery at the location where the vehicle is stopped;
acquiring, by using the vehicle stop location information, temperature data being data relating to a temperature at the vehicle stop location; and
estimating, by using the battery information and the temperature data, a state of the battery after the vehicle is stopped.

2. The battery state estimation apparatus according to claim 1, wherein
acquiring, from a weather information storage that stores temperature data for each of a plurality of spots, temperature data relevant to the vehicle stop location information,
deciding, by using the vehicle stop location information, whether the vehicle stop location is indoor or outdoor,
correcting, when the vehicle stop location is indoor, the temperature data and then estimates a state of the battery.

3. The battery state estimation apparatus according to claim 1,
deciding, by using the vehicle stop location information, whether the vehicle stop location is indoor or outdoor, wherein
acquiring, when the vehicle stop location is indoor, the temperature data from a temperature sensor installed in the vehicle stop location.

4. The battery state estimation apparatus according to claim 1, wherein
estimating a state of the battery, by further using at least one of past information indicating a past estimation result, and the temperature data used when the past information is generated.

5. The battery state estimation apparatus according to claim 1, wherein
determining, by using the temperature data, transition of a temperature at the vehicle stop location since the vehicle is stopped, and
estimating, by using the transition of the temperature, a state of the battery.

6. The battery state estimation apparatus according to claim 1, wherein,
until the vehicle is started after the vehicle is stopped,
repeatedly acquiring the battery information, and
repeatedly estimating a state of the battery.

7. The battery state estimation apparatus according to claim 1,
performing a predetermined output when an estimation result satisfies a reference.

8. The battery state estimation apparatus according to claim 7, wherein
the estimation result includes transition of a value indicating a battery remaining amount since the vehicle is stopped, and
performing the predetermined output when the vehicle is not started until timing at which, in the transition, the battery remaining amount becomes equal to or less than a reference value.

9. The battery state estimation apparatus according to claim 7, wherein repeatedly performing the predetermined output until the vehicle is started.

10. The battery state estimation apparatus according to claim 7, wherein
the predetermined output includes destination information indicating a candidate of a destination of the vehicle.

11. The battery state estimation apparatus according to claim 1, wherein
estimating a state of the battery, by using a model generated based on machine learning using, as an explanatory variable, the battery information and the temperature data, and, as an objective variable, a state of the battery,
transmitting, to an outside, when a difference between an estimation result of a state of the battery and an actual measurement value of a state of the battery is equal to or more than a reference in a case where a predetermined time elapses from the stop, at least an actual measurement value of a state of the battery and the temperature data in order to be used as at least a part of training data of the machine learning.

12. (canceled)

13. A battery state estimation method comprising,
by a computer:
acquiring vehicle stop location information indicating a vehicle stop location of a vehicle mounted with a battery, and also acquiring battery information indicating a state of the battery at the location where the vehicle is stopped;
acquiring, by using the vehicle stop location information, temperature data being data relating to a temperature at the vehicle stop location; and
estimating, by using the battery information and the temperature data, a state of the battery after the vehicle is stopped.

14. A computer-readable storage medium storing a program for causing a computer to include:
acquiring vehicle stop location information indicating a vehicle stop location of a vehicle mounted with a battery, and also acquiring battery information indicating a state of the battery at the location where the vehicle is stopped;
acquiring, by using the vehicle stop location information, temperature data being data relating to a temperature at the vehicle stop location; and
estimating, by using the battery information and the temperature data, a state of the battery after the vehicle is stopped.
